(19) United States
(12) Patent Application Publication
(10) Pub. No.: US 2020/0004446 A1
(43) Pub. Date: Jan. 2, 2020

(54) MULTI-LEVEL CELL DATA LOAD OPTIMIZATION

(71) Applicants: David Aaron Palmer, Boise, ID (US); Cory J. Reche, Boise, ID (US); Christopher Bueb, Folsom, CA (US)

(72) Inventors: David Aaron Palmer, Boise, ID (US); Cory J. Reche, Boise, ID (US); Christopher Bueb, Folsom, CA (US)

(21) Appl. No.: 16/024,201

(22) Filed: Jun. 29, 2018

(51) Int. Cl. G06F 3/06; G06F 12/02; G11C 16/20; G11C 11/56; G11C 8/12

(52) U.S. Cl. CPC G06F 3/0634; G06F 3/0679; G06F 3/061; G06F 12/0246; H04L 67/12; G11C 11/5628; G11C 8/12; G11C 2211/5641; G11C 16/20

(57) ABSTRACT

Techniques are disclosed, including a method that can include entering a first mode of operation of an apparatus including a memory device, receiving first information indicative of a subsequent download of second information at the memory device, the memory device including a first group of cells configured as multi-level cell (MLC) memory, in response to receipt of the first information, converting a portion of the first group of cells from configuration as MLC memory to configuration as single-level cell (SLC) memory, receiving and storing the second information at the memory device, and upon exiting the first mode of operation, reconfiguring at least a portion of the SLC memory to MLC memory while simultaneously maintaining storage of the second information within the memory device.

### TECHNICAL FIELD

Embodiments of the disclosure relate generally to memory systems, and more specifically, to optimizing data load in multi-level cell (MLC) memory.

### BACKGROUND

A memory system can be a storage system, such as a solid-state drive (SSD), and can include one or more memory components that store data. For example, a memory system can include memory devices such as non-volatile memory devices and volatile memory devices. In general, a host system can utilize a memory system to store data at the memory devices of the memory system and to retrieve data stored at the memory system.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment including a memory system, in accordance with some examples of the present disclosure.

FIG. 2 illustrates generally a flowchart of an example method 200 of receiving a download at a memory system during a production stage and optimizing the download to save valuable production time and resources.

FIG. 3 illustrates graphically a faster download speed of a memory system in accordance with the present subject matter.

FIG. 4 illustrates an example machine of a computer system 400 within which a set of instructions, for causing the machine to perform any one or more of the methodologies discussed herein, can be executed.

### DETAILED DESCRIPTION

Aspects of the present disclosure are directed to time-wise optimizing information downloads to multi-level cell (MLC) memory. In certain examples, an electronic device or computing environment can be downloaded at the manufacturer with information, including instructions, designed to operate the electronic device in the field. Such instructions can be part of an operating system, an application configured to run on the operating system, data for use with the application or operating system, or combinations thereof. Such download operations consume time and resources at the manufacturing stage of the electronic device and contribute to the non-fixed cost of the computing system. As such, each additional download of previously downloaded information to the computing environment at the manufacturer can decrease the margin of the computing device. During production and after a first download, the computing environment can be tested, reprocessed, and retested. Retaining the information of the first download throughout the production stage can eliminate costly download events and maintain a higher margin on the computing device.

In certain examples, the memory system of the electronic device can include multi-level cell (MLC) technology such as dual-level cells, triple-level cells (TLC), or quad-level cells (QLC). Such technology allows for increased memory density without increasing the size of the electronic device compared to earlier versions of the electronic device or competitor devices that use for example single-level cell (SLC) technology. However, downloading large blocks of information such as a data image from a host to the electronic device and more particularly to the memory of the electronic device can take longer with the memory configured as MLC compared to memory configured as SLC.

The present inventors have recognized techniques for saving time and resources when downloading large amounts of information from a host to an electronic device including MLC memory. In addition to saving time, especially during the production stage, the method also allows for storage of data in SLC-configured memory of the MLC capable memory during a subsequent heating of the electronic device such as for reflow purposes. In certain examples, MLC memory configured for SLC operation can provide more robust performance during reflow heating than MLC operation. In some examples, SLC-configured memory can be selectively reconfigured for operation as MLC memory if a particular download is larger than anticipated.

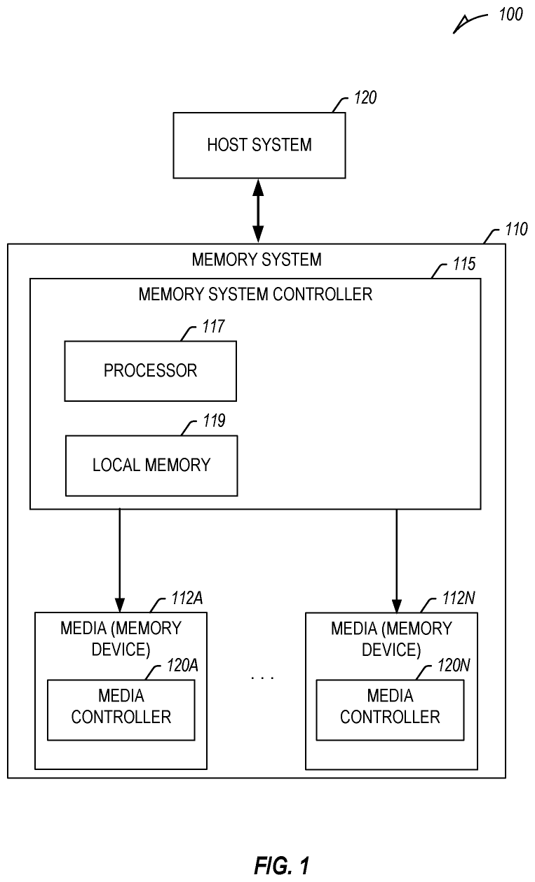

FIG. 1 illustrates an example computing environment 100 including a memory system 110, in accordance with some examples of the present disclosure. The memory system 110 can include media, such as memory devices 112A to 112N. The memory devices 112A to 112N can be volatile memory devices, non-volatile memory devices, or a combination of such. In some embodiments, the memory system is a storage system. An example of a storage system is an SSD. In some embodiments, the memory system 110 is a hybrid memory/storage system. In general, the computing environment 100 can include a host system 120 that uses the memory system 110. In some implementations, the host system 120 can write data to the memory system 110 and read data from the memory system 110.

The host system 120 can be a computing device such as a desktop computer, laptop computer, network server, mobile device, or such computing device that includes a memory and a processing device. The host system 120 or the memory system 110 can be included in a variety of products, such as IoT devices (e.g., a refrigerator or other appliance, sensor, motor or actuator, mobile communication device, automobile, drone, etc.) to support processing, communications, or control of the product. The host system 120 can include a processor, a memory card reader, or one or more other electronic devices external to the memory system 110. The host system 120 can include or be coupled to the memory system 110 so that the host system 120 can read data from or write data to the memory system 110. The host system 120 can be coupled to the memory system 110 via a physical host interface. As used herein, “coupled to” generally refers to a connection between components, which can be an indirect communicative connection or direct communicative connection (e.g., without intervening components), whether wired or wireless, including connections such as, electrical, optical, magnetic, etc. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), an eMMC™ interface, etc. The physical host interface can be used to transmit data between the host system 120 and the memory system 110. The host system 120 can further utilize an NVM Express (NVMe) interface to access the memory devices 112A to 112N when the memory system 110 is coupled with the host system 120 by the PCIe interface. The physical host interface can provide an interface for passing control, address, data, and other signals between the memory system 110 and the host system 120.

The memory system 110 is shown, by way of example, to include the memory system controller 115 and media, such as memory devices 112A to 112N. The memory devices 112A to 112N can include any combination of the different types of non-volatile memory devices and/or volatile memory devices. An example of non-volatile memory devices includes a negative-and (NAND) type flash memory. Each of the memory devices 112A to 112N can include one or more arrays of memory cells such as single-level cells (SLCs) or multi-level cells (MLCs) (e.g., triple-level cells (TLCs) or quad-level cells (QLCs)). In some implementations, a particular memory device can include both an SLC portion and an MLC portion of memory cells (e.g., memory cells having different bit capacities per cell). Each of the memory cells can store bits of data (e.g., data blocks) used by the host system 120. Although non-volatile memory devices such as NAND type flash memory are described, the memory devices 112A to 112N can be based on any other type of memory such as a volatile memory. In some implementations, the memory devices 112A to 112N can be, but are not limited to, random access memory (RAM), read-only memory (ROM), dynamic random-access memory (DRAM), synchronous dynamic random-access memory (SDRAM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many Flash-based memory, cross point non-volatile memory can perform a write in-place operation, where a non-volatile memory cell can be programmed without the non-volatile memory cell being previously erased. Furthermore, the memory cells of the memory devices 320 can be grouped as a number of devices, planes, sub-blocks, blocks, or pages that can refer to a unit of the memory device used to store data.

In an example, the memory system 110 can be a discrete memory and/or storage device component of the host system 120. In other examples, the memory system 110 can be a portion of an integrated circuit (e.g., system on a chip (SOC), etc.), stacked or otherwise included with one or more other components of the host system 120.

Each of the media devices 112A to 112N can include a media controller (e.g., media controllers 130A to 130N) to manage the memory cells of the memory devices 112A to 112N.

The memory system 110 can include a memory system controller 115 that can communicate with the memory devices 112A to 112N to perform operations such as reading data, writing data, or erasing data at the memory devices 112A to 112N and other such operations. The memory system controller 115 can include hardware such as one or more integrated circuits and/or discrete components, a buffer memory, or a combination thereof. The memory system controller 115 can be a microcontroller, special purpose logic circuitry (e.g., a field programmable gate array (FPGA), an application specific integrated circuit (ASIC), etc.), or other suitable processor. The memory system controller 115 can include a processor (processing device) 117 configured to execute instructions stored in local memory 119. In the illustrated example, the local memory 119 of the memory system controller 115 includes an embedded memory configured to store instructions for performing various processes, operations, logic flows, and routines that control operation of the memory system 110, including handling communications between the memory system 110 and the host system 120. In some embodiments, the local memory 119 can include memory registers storing, e.g., memory pointers, fetched data, etc. The local memory 119 can also include read-only memory (ROM) for storing micro-code. While the example memory system 110 in FIG. 1 has been illustrated as including the memory system controller 115, in another embodiment of the present disclosure, a memory system 110 may not include a memory system controller 115, and may instead rely upon external control (e.g., provided by an external host, or by a processor or controller separate from the memory system).

In general, the memory system controller 115 can receive commands or operations from the host system 120 and can convert the commands or operations into instructions or appropriate commands to achieve the desired access to the memory devices 112A to 112N. The memory system controller 115 can be responsible for other operations such as wear leveling operations (e.g., garbage collection operations, reclamation), error detection and error-correcting code (ECC) operations, encryption operations, caching operations, block retirement, and address translations between a logical block address and a physical block address that are associated with the memory devices 112A to 112N. The memory system controller 115 can further include host interface circuitry to communicate with the host system 120 via the physical host interface. The host interface circuitry can convert the commands received from the host system into command instructions to access the memory devices 112A to 112N as well as convert responses associated with the memory devices 112A to 112N into information for the host system 120.

In an example, the memory system can include MLC-configured memory and the controller can receive an indication of a subsequent download. In some examples, the indication can indicate that the computing environment 100 is in a production stage. Such an indication can trigger the memory system controller to allocate some of the MLC-configured memory as SLC-configured memory. In general, a production mode status can indicate that the computing environment is more likely to encounter extreme environmental conditions as part of the production process. Such extreme conditions can include heating for reflow, electrical testing, electromagnetic testing, electrostatic testing, or combination thereof. Downloading information to the computing system takes time and resources during the production stage. Information downloaded to the computing environment for storage on the memory system during production can include the operating system and applications that may be used for testing before and after the computing environment is subjected to the extreme conditions, and may well be the operating system and applications the finished computing environment may use in the field. As such, in order to reduce the chance of losing the downloaded information when the computing environment is subjected to extreme conditions, the memory controller can store the information of the subsequent download in a version of the memory that provides the best performance under extreme conditions. In certain examples, SLC-configured memory is more reliable for retaining information when a computing environment is subject to extreme conditions compared to MLC-configured memory. In addition, SLC-configured memory can be faster than MLC-configured memory when storing information, such as when receiving and storing the subsequent download information.

In certain examples while the computing environment is in a production stage, the indication of the production state, or a separate indication, can include an estimate of the size of the subsequent production download. Based on the amount of memory available when configured as MLC memory, the amount of memory available when configured as SLC memory, and the estimated size of the download, the memory controller can allocate, or reconfigure, a portion of the MLC memory to operate as SLC memory.

For example, if the size of the information to be downloaded is estimated to be less than the potentially available SLC-configured memory, the memory controller can configure enough MLC memory to SLC memory to completely save the information of the subsequent download in SLC-configured memory only.

In certain examples, if the size of the subsequent download is larger than the totality of the potentially available SLC-configured memory, the memory controller can determine an optimal amount of SLC-configured memory in combination with MLC memory to completely store the subsequent download while providing the maximum transfer throughput to the SLC-configured memory during the download. Such determination can provide the quickest download of the information while at the same time saving a significant amount of the information in robust SLC-configured memory.

In certain examples, the actual size of the download information can be more than the estimated size. As information is downloaded beyond the estimated size, the memory controller can reconfigure SLC-configured memory back to MLC memory to provide storage capacity for the amount information of the download beyond the estimated size of the download information.

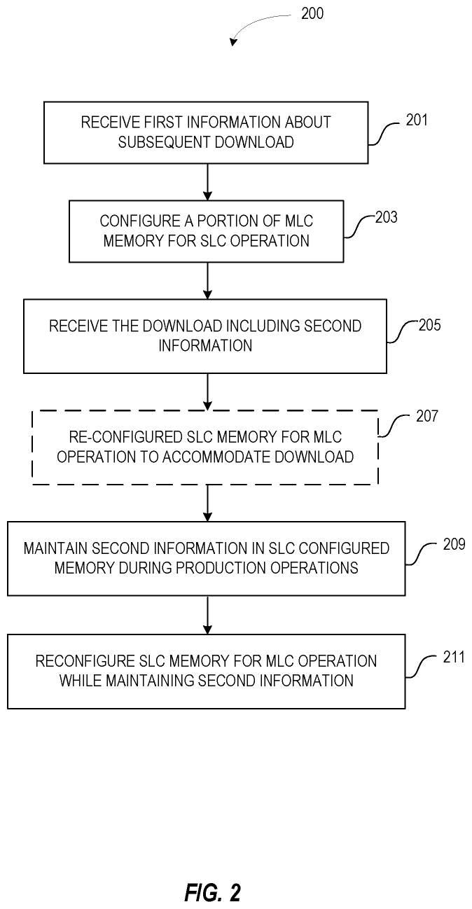

FIG. 2 illustrates generally a flowchart of an example method 200 of receiving a download at a memory system during a production stage and optimizing the download to save valuable production time and resources. At 201, the memory system can receive an indication or first information about a subsequent production mode download. In certain examples, the first information can include an estimate of the size of the download. At 203, in response to the first information, the memory system can configure a portion of MLC memory as SLC memory to allow at least a portion of the subsequent download to be accomplished faster. The amount of SLC allocated can depend on many factors including, but not limited to, size of the download, MLC memory available, maximum fill percentage, etc. At 205, the memory system can receive the download. In certain examples, during the download, download information can be first received and stored at the SLC-configured memory. Upon filling the SLC-configured memory, the download information can then be received at the MLC memory if need be. In some situations, the size estimate received at the memory system can be inaccurate. If the estimate is low, the memory system can have a couple of options to accommodate the extra download information.

In certain examples, the maximum fill percentage can be less than 100% and the additional download information can be received and saved to the remaining open memory beyond the maximum fill percentage. In certain examples, download information saved in the SLC-configured memory can be buffered, at 207, the SLC-configured memory can be re-configured to MLC memory, and the buffered and additional download information saved to the recently configured MLC memory. In some examples, a combination of the above options for handling the additional download information can be employed.

At 209, the system or computing environment can continue through production after the download. In certain examples, the computing system can be subjected to extreme environmental conditions during subsequent production processes. Such processes can include but are not limited to re-flow soldering. As discussed above, downloading large amounts of information to the computing environment from a host during production requires dedicated time and resources. It is not desirable to have to reload information if such a reload can be avoided. To that end, the production download discussed above attempts to maintain as much of the download information in SLC-configured memory. SLC-configured memory can generally maintain information during extreme environmental conditions better than MLC-configured memory. Therefore, for production downloads of information, such as an image of an operating system, as much of the download production information as reasonably possible is stored in SLC-configured memory. After production mode has ended, or during a transition out of production mode, at 211, the downloaded data can simultaneously be retained in the memory system as the SLC-configured memory is converted back to MLC-configured memory to provide the computing environment with the predetermined memory capacity.

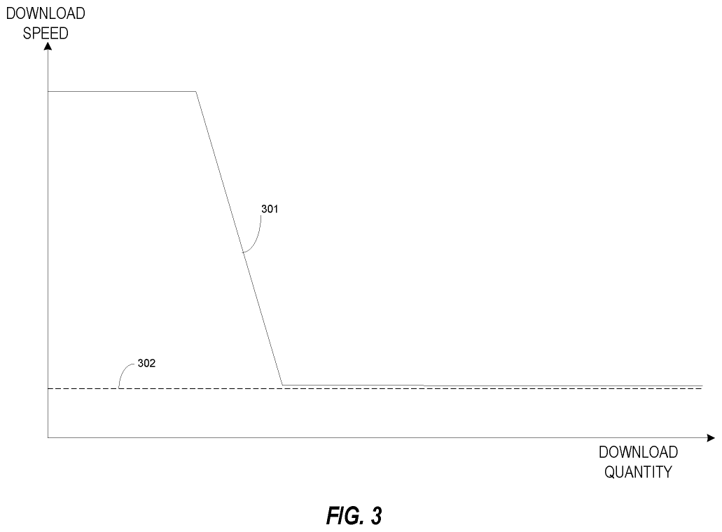

FIG. 3 illustrates graphically a faster download speed of a memory system in accordance with the present subject matter compared to a download using only MLC-configured memory. The graph shows a first plot 301 of the download speed of an example memory system using SLC-configured memory to download. Such a download can include, for example, a system image during production. Such a download can be intended to remain with the system after production and can include the operating system and related applications and files for use in the field. The graph shows a second plot 302 of a download to the memory system using only MLC-configured memory to receive and save the image. In the illustrated examples, the size of the image is larger than the available memory if all the memory were configured for SLC operation. The second plot 302 using an MLC only download shows a very consistent download speed through the entire download. The first plot 301 of the download using SLC-configured memory shows much higher download speed up to the time in the download when the SLC memory is filled. Once the SLC-configured memory is filled, the download begins to fill the MLC-configured memory and the download speed falls accordingly. The higher download speed associated with downloading the SLC-configured memory represents significant time and resource savings for a production stage. In certain examples, since at least a portion of the image is stored in SLC-configured memory during additional production processes, such as re-flow, the image has a better chance of being retained than of the entire image were stored in MLC memory. Thus, additional downloads may be avoided using SLC-configured memory. Post-production, the memory system can retain the image and convert the SLC-configured memory back to MLC-configured operation to provide a specified memory capacity for a user.

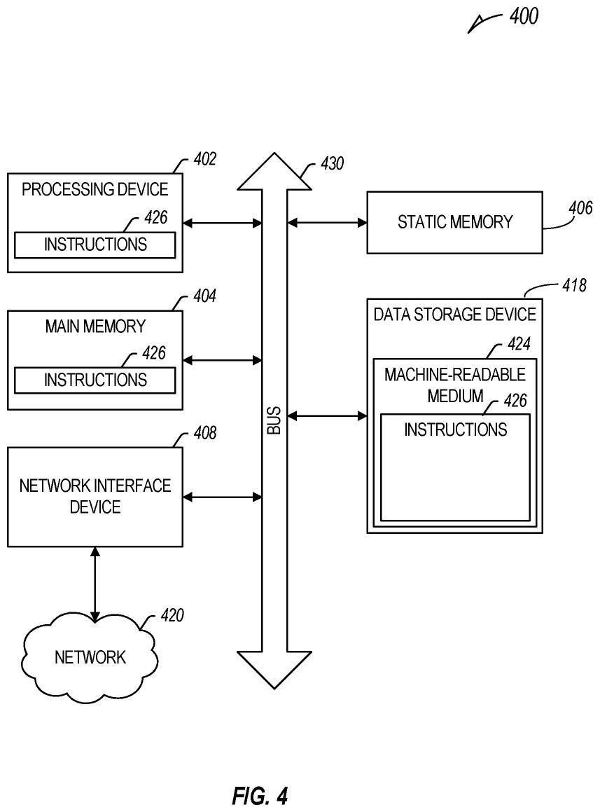

FIG. 4 illustrates an example machine of a computer system 400 within which a set of instructions, for causing the machine to perform any one or more of the methodologies discussed herein, can be executed. In some implementations, the computer system 400 can correspond to a host system (e.g., the host system 120 of FIG. 1) that includes or utilizes a memory system (e.g., the memory system 110 of FIG. 1) or can be used to perform the operations of a controller. In alternative implementations, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random-access memory (DRAM) such as synchronous DRAM (SDRAM) or Rambus DRAM (RDRAM), etc.), a static memory 406 (e.g., flash memory, static random-access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions or software 426 embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory system 110 of FIG. 1.

In one implementation, the instructions 426 include instructions to implement functionality corresponding to reconfiguring memory operation from MLC to SLC for downloading information such as an image during production and saving and reconfiguring memory operation of the SLC memory to MLC memory after production. While the machine-readable storage medium 424 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

### EXAMPLES

Example 1 is a method comprising: entering a first mode of operation of an apparatus including a memory device; receiving first information indicative of a subsequent download of second information at the memory device, the memory device including a first group of memory cells configured as multi-level cell (MLC) memory; in response to receipt of the first information, converting a portion of the first group of memory cells from configuration as MLC memory to configuration as single-level cell (SLC) memory; receiving and storing the second information at the memory device; and upon exiting the first mode of operation, reconfiguring at least a portion of the SLC memory to MLC memory while simultaneously maintaining storage of the second information within the memory device.

In Example 2, the subject matter of Example 1, including heating the memory device after receiving and storing the second information and before reconfiguring the portion of the SLC memory.

In Example 3, the subject matter of Example 2, wherein the heating includes heating the memory device to a heat level characteristic of reflowing solder on the memory device or on a component of the apparatus including the memory device.

In Example 4, the subject matter of any of Examples 1-3, wherein the receiving the first information includes receiving an estimate of a size of the microsecond information.

In Example 5, the subject matter of Example 4, wherein the converting includes determining a maximum amount of SLC-configurable memory available for the storing of the second information based on the estimated size of the second information and a capacity of the memory device.

In Example 6, the subject matter of any of Examples 4-5, wherein receiving and storing the second information includes: determining the estimated size of the second information is smaller than an actual size of the second information; during the first mode of operation, reconfiguring a portion of the SLC memory to MLC memory while maintaining any second information stored on the portion of the SLC memory; and receiving additional second information into the MLC memory.

In Example 7, the subject matter of any of Examples 1-6, wherein the first mode of operation is a manufacturing mode of operation.

In Example 8, the subject matter of any of Examples 1-7, wherein the second information includes an operating system.

In Example 9, the subject matter of any of Examples 1-8, wherein the second information includes an automotive navigation, communication, and entertainment operating system.

In Example 10, the subject matter of Example 9, wherein the second information includes automotive navigation, communication, or entertainment applications.

In Example 11, the subject matter of any of Examples 1-10, wherein the second information includes an automotive diagnostic operating system.

In Example 12, the subject matter of any of Examples 1-11, wherein the MLC memory includes triple-level cell (TLC) memory.

In Example 13, the subject matter of any of Examples 1-12, wherein the MLC memory includes quad-level cell (QLC) memory.

Example 14 is a memory circuit including: memory cells configured to provide multi-level cell (MLC) storage; and a controller operably coupled to the memory cells, the controller configured to perform operations, comprising: receiving an indication of a production mode of a device including the memory circuit; receiving an estimated size of a subsequent download during the production mode, to configure at least a portion of the memory cells from operation as MLC storage to operation as single-level cell (SLC) storage in response to the estimated size; receiving a direct the subsequent download to the memory cells, and upon receiving an indication that the device is leaving the production mode, reconfiguring the at least portion of the memory cells from operation as SLC storage to operation as MLC storage, simultaneously maintaining, within the memory cell, information included as part of the subsequent download.

In Example 15, the subject matter of Example 14, wherein the memory cells are configured to provide triple-level cell (TLC) storage.

In Example 16, the subject matter of any of Examples 14-15, wherein the memory cells are configured to provide quad-level cell (QLC) storage.

Example 17 is a machine-readable medium, comprising instructions, which when executed by a machine, cause the machine to perform operations comprising: receiving a first indication indicative of a production mode of an apparatus including a memory device; receiving first information indicative of a subsequent download of second information at the memory device, the memory device including a first group of cells configured to operate as multi-level cell (MLC) memory; in response to receipt of the first information, converting a portion of the first group of cells from operation as MLC memory to operation as single-level cell (SLC) memory; receiving and storing the second information at the memory device; and upon exiting the first mode of operation, reconfiguring at least a portion of the SLC memory to operate as MLC memory while simultaneously maintaining storage of the second information within the memory device.

In Example 18, the subject matter of Example 17, wherein the operations further comprise: determining reception of the second information exceeds a size indication received with the first information and, simultaneous with receiving the second information, reconfiguring some of the SLC memory to operate as MLC memory to accommodate storing a portion of the second information in excess of the size indication.

In Example 19, the subject matter of Example 18, wherein the reconfiguring the at least a portion of the SLC memory includes reconfiguring the at least a portion of the SLC memory to operate as triple-level cell (TLC) memory.

Example 20 is at least one machine-readable medium including instructions that, when executed by processing circuitry, cause the processing circuitry to perform operations to implement of any of Examples 1-19.

Example 21 is an apparatus comprising means to implement of any of Examples 1-19.

Example 22 is a system to implement of any of Examples 1-19.

Example 23 is a method to implement of any of Examples 1-19.

What is claimed is:

1. A method comprising:
entering a first mode of operation of an apparatus including a memory device;
receiving first information indicative of a subsequent download of second information at the memory device, the memory device including a first group of memory cells configured as multi-level cell (MLC) memory;
in response to receipt of the first information, converting a portion of the first group of memory cells from configuration as MLC memory to configuration as single-level cell (SLC) memory;
receiving and storing the second information at the memory device; and
upon exiting the first mode of operation, reconfiguring at least a portion of the SLC memory to MLC memory while simultaneously maintaining storage of the second information within the memory device.

2. The method of claim 1, including heating the memory device after receiving and storing the second information and before reconfiguring the portion of the SLC memory.

3. The method of claim 2, wherein the heating includes heating the memory device to a heat level characteristic of reflowing solder on the memory device or on a component of the apparatus including the memory device.

4. The method of claim 1, wherein the receiving the first information includes receiving an estimate of a size of the microsecond information.

5. The method of claim 4, wherein the converting includes determining a maximum amount of SLC-configurable memory available for the storing of the second information based on the estimated size of the second information and a capacity of the memory device.

6. The method of claim 4, wherein receiving and storing the second information includes:
determining the estimated size of the second information is smaller than an actual size of the second information;
during the first mode of operation, reconfiguring a portion of the SLC memory to MLC memory while maintaining any second information stored on the portion of the SLC memory; and
receiving additional second information into the MLC memory.

7. The method of claim 1, wherein the first mode of operation is a manufacturing mode of operation.

8. The method of claim 1, wherein the second information includes an operating system.

9. The method of claim 1, wherein the second information includes an automotive navigation, communication, and entertainment operating system.

10. The method of claim 9, wherein the second information includes automotive navigation, communication, or entertainment applications.

11. The method of claim 1, wherein the second information includes an automotive diagnostic operating system.

12. The method of claim 1, wherein the MLC memory includes triple-level cell (TLC) memory.

13. The method of claim 1, wherein the MLC memory includes quad-level cell (QLC) memory.

14. A memory circuit including:
memory cells configured to provide multi-level cell (MLC) storage; and
a controller operably coupled to the memory cells, the controller configured to perform operations, comprising:
receiving an indication of a production mode of a device including the memory circuit;
receiving an estimated size of a subsequent download during the production mode, to configure at least a portion of the memory cells from operation as MLC storage to operation as single-level cell (SLC) storage in response to the estimated size;
receiving a direct the subsequent download to the memory cells, and
upon receiving an indication that the device is leaving the production mode, reconfiguring the at least portion of the memory cells from operation as SLC storage to operation as MLC storage, simultaneously maintaining, within the memory cell, information included as part of the subsequent download.

15. The memory circuit of claim 14, wherein the memory cells are configured to provide triple-level cell (TLC) storage.

16. The memory circuit of claim 14, wherein the memory cells are configured to provide quad-level cell (QLC) storage.

17. A machine-readable medium, comprising instructions, which when executed by a machine, cause the machine to perform operations comprising:
receiving a first indication indicative of a production mode of an apparatus including a memory device;
receiving first information indicative of a subsequent download of second information at the memory device, the memory device including a first group of cells configured to operate as multi-level cell (MLC) memory;
in response to receipt of the first information, converting a portion of the first group of cells from operation as MLC memory to operation as single-level cell (SLC) memory;
receiving and storing the second information at the memory device; and
upon exiting the first mode of operation, reconfiguring at least a portion of the SLC memory to operate as MLC memory while simultaneously maintaining storage of the second information within the memory device.

18. The machine-readable medium of claim 17, wherein the operations further comprise:
determining reception of the second information exceeds a size indication received with the first information and, simultaneous with receiving the second information, reconfiguring some of the SLC memory to operate as MLC memory to accommodate storing a portion of the second information in excess of the size indication.

19. The machine-readable medium of claim 18, wherein the reconfiguring the at least a portion of the SLC memory includes reconfiguring the at least a portion of the SLC memory to operate as triple-level cell (TLC) memory.
